(19) United States
(12) Patent Application Publication
(10) Pub. No.: US 2008/0012477 A1
(43) Pub. Date: Jan. 17, 2008

(54) Organic light emitting diode display and method for manufacturing thereof

(75) Inventors: Won-Hoe Koo, Suwon-si (KR); Hoon Kim, Hwaseong-si (KR); Jung-Mi Choi, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/825,947

(22) Filed: Jul. 9, 2007

(30) Foreign Application Priority Data
Jul. 12, 2006 (KR) 10-2006-0065320

(51) Int. Cl. H01J 1/62; H01J 9/02; H01L 51/56

(52) U.S. Cl. 313/504; 445/24

(57) ABSTRACT

An OLED display and a manufacturing method thereof are provided. The OLED display includes a substrate, a plurality of TFTs, a plurality of pixel electrodes, an organic light emitting member, and an encapsulation member. The substrate includes a display region and a non-display region. The TFTs are formed on the display region. The pixel electrodes are connected to the TFTs. The organic light emitting member is formed on the pixel electrodes. The common electrode is formed on the organic light emitting member. The encapsulation member is formed on the common electrode and includes heat conductive particles having heat conductivity of about 10 W/mK. The OLED display reduces air and moisture penetration of the organic light emitting member or the electrodes using heat conductive particles, and quickly discharges the heat generated from the organic light emitting member or the electrode.

### CROSS-REFERENCE TO RELATED APPLICATION

This application claims priority to and the benefit of Korean Patent Application No. 10-2006-0065320 filed in the Korean Intellectual Property Office on Jul. 12, 2006, the entire contents of which are incorporated herein by reference.

### TECHNICAL FIELD

The present invention relates to an organic light emitting diode (OLED) display and a method for manufacturing the same.

### BACKGROUND

The current trend in monitors and television sets is toward thinner and lighter displays. In order to satisfy such requirements, liquid crystal displays (LCDs) have replaced cathode ray tube (CRT) displays.

However, an LCD requires an additional backlight because the LCD is a passive light emitting device. Also, the LCD has problems in response speed and viewing angle.

As a display that may overcome these problems, an organic light emitting diode (OLED) display has being receiving attention.

The OLED display includes a pixel electrode, a common electrode, and an emitting layer interposed between the two electrodes, one for injecting electrons and the other for injecting holes to the emitting layer. The injected electrons and holes are coupled at the emitting layer, and excitons are thereby formed. The formed excitons emit light while discharging energy. Since the OLED display does not require an additional light source, such as the backlight of an LCD display, the power consumption of the OLED display may be lower. Also, the OLED display may have a faster response speed, a wider viewing angle, and a superior contrast ratio.

However, moisture or air may penetrate the OLED display from the outside, which may accelerate deterioration of the pixel electrode, the common electrode, and the emitting layer.

In addition, the OLED display may generate not only light but also a great deal of heat while emitting the light. Any associated temperature increase from the generated heat may further accelerate deterioration of the pixel electrode, the common electrode, and the emitting layer.

This deterioration may degrade the display performance of the OLED display, for example, the brightness and contrast, and also shorten the lifetime of the OLED display.

The above information disclosed in this Background section is only for enhancement of understanding of the background of the invention and therefore it may contain information that does not form the prior art that is already known in this country to a person of ordinary skill in the art.

### SUMMARY

The present invention has been made in an effort to provide an organic light emitting diode display and a method for manufacturing the same having advantages of improved performance and a longer lifetime.

Herein, W denotes watts as a unit of power, m denotes meters as a unit of length, and K denotes Kelvin as a unit of absolute temperature.

An exemplary embodiment of the present invention provides an OLED display that includes a substrate, a plurality of TFTs, a plurality of pixel electrodes, an organic light emitting member, and an encapsulation member. The substrate includes a display region and a non-display region, the TFTs are formed on the display region, and the pixel electrodes are connected to the associated TFTs. The organic light emitting members are formed on the associated pixel electrodes, the common electrode is formed on the organic light emitting members, and an encapsulation member formed on the common electrode and having a sealing resin with heat conductive particles distributed therein, where the heat conductive particles have heat conductivity of about 10 W/mK or greater.

The heat conductive particles may be of at least two different sizes.

The heat conductive particles may include at least one of alumina particles and graphite particles.

The heat conductivity of the alumina particles may be about 10 W/mK to 35 W/mK.

The heat conductivity of the graphite particles may be about 100 W/mK to 200 W/mK.

The heat conductive particles may include alumina particles, and the alumina particles may be formed on at least two different sizes of spherical particles. The heat conductive particles may include graphite particles, and the graphite particles include at least two different sizes of plate-shaped particles.

The volume of the heat conductive particles may be about 5% to 75% of the volume of a sealing resin.

The thickness of the sealing resin is about 10 μm to 100 μm.

The heat conductive particles may be alumina particles, and include a first spherical particles, a second spherical particles, and a third spherical particles that have different sizes, wherein the diameter of the first spherical particles is about 5 μm to 75 μm, the diameter of the second spherical particles is about 2 μm to 20 μm, and the diameter of the third spherical particles is about 0.1 μm to 5 μm.

The heat conductive particles may be graphite particles, and include a first plate-shaped particle, a second plate-shaped particle, and a third plate-shaped particle that have different sizes, wherein, a length of a long side of the first plate-shaped particles is about 5 μm to 50 μm, a length of a long side of the second plate-shaped particle is about 2 μm to 20 μm, and, a length of a long side of the third plate-shaped particles is about 0.1 μm to 5 μm.

The sealing resin may be formed on at least a portion of the common electrode.

The sealing member may further include a protection substrate adhered to the sealing resin on a side opposite the common electrode.

The OLED display may further include a buffer layer formed between the common electrode and the encapsulation member.

The buffer layer may be at least one of an organic layer and an inorganic layer.

The sealing resin may be formed along the non-display region of the insulating substrate and the encapsulation member may further include a protective substrate adhered to the sealing resin to cover the common electrode.

Another embodiment of the present invention provides a method of manufacturing an organic light emitting diode (OLED) display. In the method, a plurality of thin film transistors may be formed on a display region of an insulating substrate having the display region and a non-display region. Then, a pixel electrode connected to the thin film transistor may be formed. An organic light emitting member may be formed on the pixel electrode, and a common electrode may be formed on the organic light emitting member associated with each of the plurality of thin film transistors. Then, an encapsulation member having a sealing resin with heat conductive particles distributed therein may be formed. Herein, the heat conductive particles have heat conductivity of about 10 W/mK or greater.

The forming of the encapsulation member may include forming a sealing resin material with the heat conductive particles distributed along at least the non-display region, and hardening the sealing resin material using at least one of heat and ultraviolet rays.

The method may further include forming a buffer layer on the common electrode between the forming of the common electrode and the forming of the encapsulation member.

In the forming of the encapsulation member, the heat conductive particles distributed in the sealing resin may have a plurality of sizes.

In the forming the encapsulation member, the heat conductive particles distributed in the sealing resin may include at least one of alumina particles and graphite particles.

### BRIEF DESCRIPTION OF THE DRAWINGS

FIG. 1 is an equivalent circuit diagram illustrating an OLED display according to an embodiment of the present invention.

FIG. 2 is a plane view of an OLED display according to an embodiment of the present invention.

FIG. 3 is a cross-sectional view of the OLED display shown in FIG. 2 taken along the line III-III.

FIG. 4 is a magnified view of a region A in the OLED display shown in FIG. 2.

FIG. 5A and FIG. 6 are cross-sectional views of the OLED display shown in FIG. 4 taken along the lines Va-Va and VI-VI.

FIG. 5B is a magnified view of a region B in the OLED display shown in FIG. 5A.

FIG. 7, FIG. 10, FIG. 13, FIG. 16, and FIG. 19 show layouts of the OLED display shown in FIG. 4 to FIG. 6 for describing a method of manufacturing the OLED display according to an embodiment of the present invention.

FIG. 8 and FIG. 9 are cross-sectional views of the OLED display shown in FIG. 7 taken along the line VIII-VIII and the line IX-IX.

FIG. 11 and FIG. 12 are cross-sectional views of the OLED display shown in FIG. 10 taken along the line XI-XI and the line XII-XII.

FIG. 14 and FIG. 15 are cross-sectional views of the OLED display shown in FIG. 13 taken along the line XIV-XIV and the line XV-XV.

FIG. 17 and FIG. 18 are cross-sectional views of the OLED display shown in FIG. 16 taken along the line XVII-XVII and the line XVIII-XVIII.

FIG. 20 and FIG. 21 are cross-sectional view of the OLED display shown in FIG. 19 taken along the line XX-XX and the line XXI-XXI.

FIG. 22 and FIG. 23 are cross-sectional views of FIG. 20 and FIG. 21.

FIG. 24 and FIG. 25 are cross-sectional views of FIG. 22 and FIG. 23.

FIG. 26 to FIG. 29 are cross-sectional views of OLED displays according to another embodiment of the present invention.

### DETAILED DESCRIPTION

Hereinafter, the present invention will be described more fully with reference to the accompanying drawings, in which preferred embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Organic light emitting diode (OLED) displays according to embodiments of the present invention are a bottom emission type.

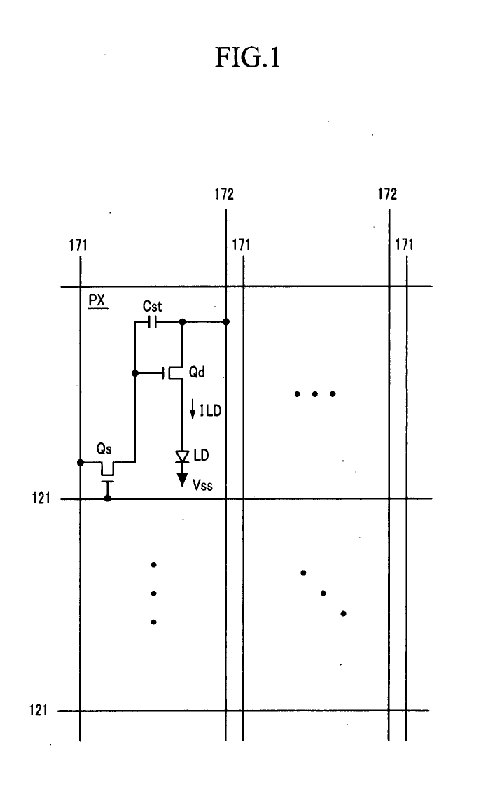

First, an OLED display according to an embodiment of the present invention will be described with reference to FIG. 1.

FIG. 1 is an equivalent circuit diagram illustrating an OLED display.

Referring to FIG. 1, the OLED display includes a plurality of signal lines 121, 171, and 172 and a plurality of pixels arranged in an approximate matrix form and connected to the signal lines 121, 171, and 172.

The signal lines includes a plurality of gate lines 121 for transferring a gate signal (scan signal), a plurality of data lines 171 for transferring a data signal, and a plurality of driving voltage lines 172 for transferring a driving voltage. The gate lines 121 substantially extend in an approximate row direction and are parallel to each others. The data lines 171 and the driving voltage lines 172 substantially extend in a column direction and are parallel to each others.

Each pixel PX includes a switching transistor Qs, a driving transistor Qd, a storage capacitor Cst, and an organic light emitting diode (OLED) LD. The switching transistor Qs includes a control terminal, an input terminal, and an output terminal. The control terminal is connected to the gate line 121, the input terminal is connected to the data line 171, and the output terminal is connected to the driving transistor Qd, respectively. The switching transistor Qs transfers the data signal supplied from the data line 171 to the driving transistor Qd in response to a scan signal supplied to the gate line 121.

The driving transistor Qd also includes a control terminal, an input terminal, and an output terminal. The control terminal is connected to the switching transistor Qs, the input terminal is connected to the driving voltage line 172, and the output terminal is connected to the organic light emitting diode LD, respectively. The driving transistor Qd flows an output current ILD having an amplitude that varies according to the voltage provided between the control terminal and the output terminal.

The storage capacitor Cst is coupled between the control terminal and the input terminal in the driving transistor Qd. The storage capacitor Cst charges the data signal supplied to the control terminal of the driving transistor Qd and sustains the charged data signal after turning off the switching transistor Qs.

The organic light emitting diode LD includes an anode connected to the output terminal of the driving transistor Qd and a cathode connected to a common voltage Vss. The organic light emitting diode LD displays images by emitting the light with varied intensity according to the output current ILD of the driving transistor Qd.

The switching transistor Qs and the driving transistor Qd are n− channel filed effect transistors (FET). However, at least one of the switching transistor Qs and the driving transistor Qd may be a p-channel FET. Also, the coupling relationship between the transistors Qs and Qd, the storage capacitor Cst, and the organic light emitting diode LD may change.

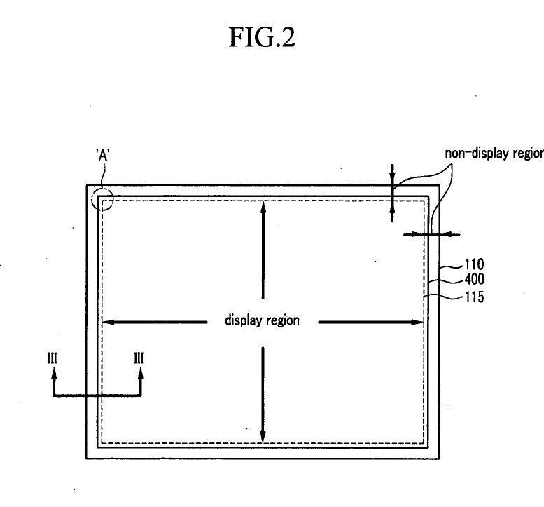

Hereinafter, the detailed structure of the OLED display shown in FIG. 1 will be described with reference to FIG. 2 to FIG. 6.

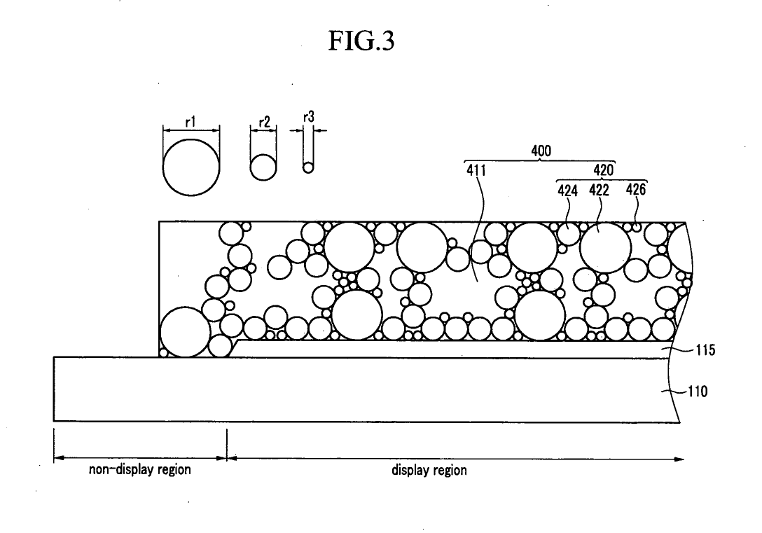

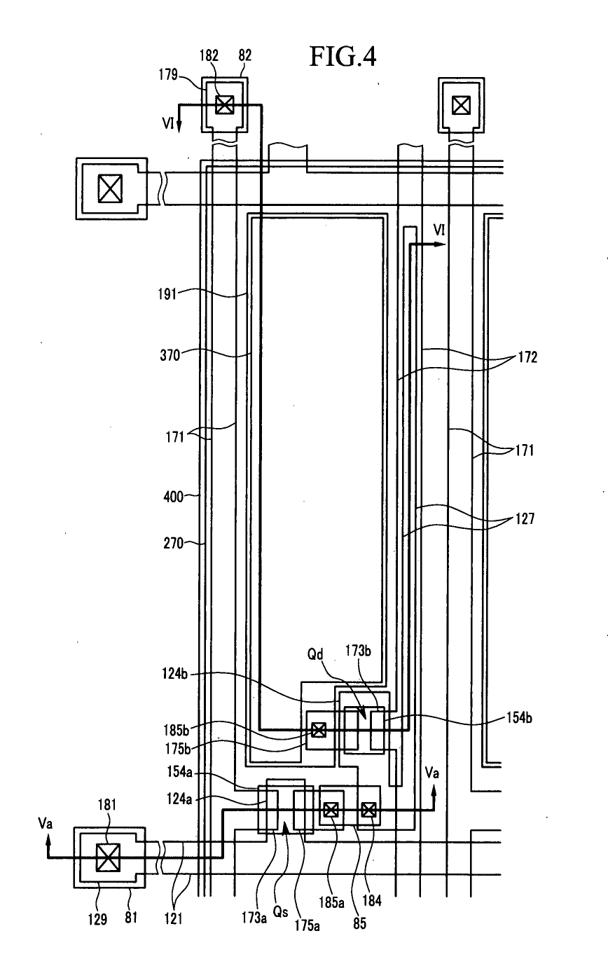

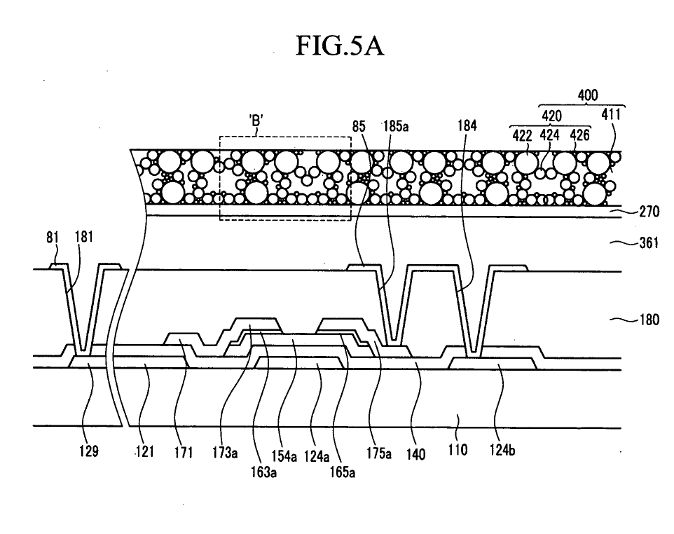

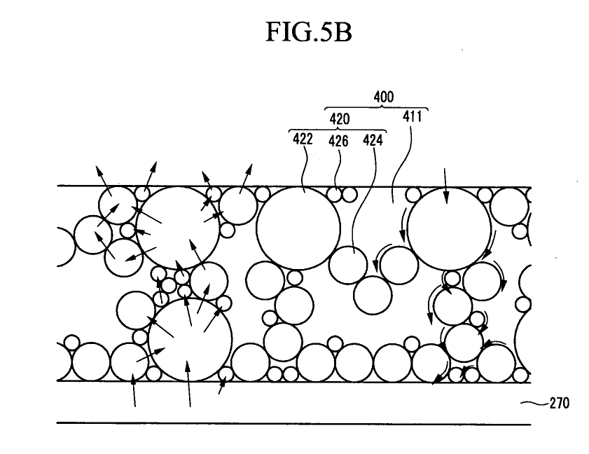

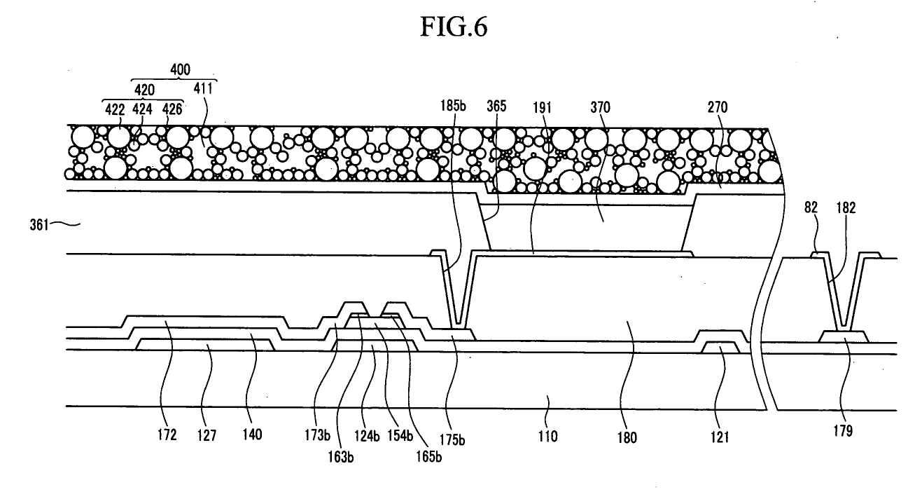

FIG. 2 is a plan view of an OLED display according to an embodiment of the present invention, FIG. 3 is a cross-sectional view of the OLED display shown in FIG. 2 taken along the line III-III, FIG. 4 is an magnified view of a region A in the OLED display shown in FIG. 2, FIG. 5A and FIG. 6 are cross-sectional views of the OLED display shown in FIG. 4 taken along the lines Va-Va and VI-VI, and FIG. 5B is a magnified view of a region B in the OLED display shown in FIG. 5A.

Referring to FIG. 4, a plurality of gate lines 121 each having a first control electrode 124a, and a plurality of gate conductors having a plurality of second control electrodes 124b are formed on an insulating substrate 110.

The insulating substrate 110 includes a display region and non-display regions, and is made of transparent glass or plastic.

The gate lines 121 transfer a gate signal and substantially extend in a horizontal direction. Each of the gate lines 121 includes a wide end 129 for being coupled to other layers or an external driving circuit, and the first control electrode 124a upwardly extends from the gate line 121. When a gate driving circuit (not shown) generating a gate signal is directly integrated on the insulating substrate 110, the gate line 121 is extended to be directly connected to the gate driving circuit.

The second control electrode 124b is separated from the gate line 121, and includes a storage electrode 127 that extends upwardly after extending first downwardly and then in the rightward direction.

The gate conductors 121 and 124b may be made of an aluminum group metal such as aluminum or an aluminum alloy, a silver group metal such as silver or a silver alloy, a copper group metal such as copper or a copper alloy, a molybdenum group metal such as molybdenum or a molybdenum alloy, chromium, tantalum, and titanium. However, they may have a multilayer structure including two conductive layers (not shown) having different physical characteristics.

The sides of the gate conductors 121 and 124b are inclined from the insulating substrate 110, and it is preferable that the inclination angle is about 30° to about 80°.

A gate insulating layer 140 may be made of silicon nitride or silicon oxide is formed on the gate conductors 121 and 124b.

A plurality of first semiconductors 154a and a plurality of second semiconductors 154b, which are made of hydrogenated amorphous silicon (a-Si) or polysilicon, are formed on the gate insulating layer 140. The first semiconductors 154a are placed on the first control electrode 124a, and the second semiconductors 154b are placed on the second control electrode 124b.

A plurality of pairs of the first ohmic contacts 163a and 165a and a plurality of pairs of the second ohmic contacts 163b and 165b may be formed on the first and second semiconductors 154a and 154b, respectively. The ohmic contacts 163a, 163b, 165a, and 165b may be formed in an island shape. The ohmic contacts 163a, 163b, 165a, and 165b may be made n+ hydrogenated amorphous silicon densely doped with an n-type impurity such as P, or may be made of silicide.

A plurality of data conductors, each of which includes a plurality of data lines 171, a plurality of driving voltage lines 172, a plurality of the first and second output electrodes 175a and 175b, are formed on the ohmic contacts 163a, 163b, 165a, and 165b and the gate insulating layer 140.

The data lines 171 transfer the data signal and substantially extend in a vertical direction so as to cross the gate lines 121. Each of the data lines 171 includes a plurality of the first input electrodes 173a extending toward the first control electrode 124a and a wide end 179 to be connected to another layer or an external driving circuit. When a data driving circuit (not shown) that generates a data signal is directly integrated on the substrate 110, the data line 171 extends to be directly connected to the data driving circuit.

The driving voltage lines 172 transfer a driving voltage and basically extend in the vertical direction to cross the gate lines 121. Each of the driving voltage lines 172 includes a plurality of the second input electrodes 173b extending toward the second control electrodes 124b. The driving voltage line 172 is overlapped with a sustain electrode 127.

The first and second output electrodes 175a and 175b are separated from one another, and are also separated from the data lines 171 and the driving voltage lines 172. The first input electrode 173a and the first output electrode 175a face one another with the first control electrode 124a as a center, and the second input electrode 173b and the second output electrode 175b face one another with the second control electrode 124b as a center.

It is preferable that the data conductors 171, 172, 175a, and 175b may be made of a refractory material such as Mo, Cr, Ta, and Ti, and alloys thereof, and may be made in a multi-layer structure including a refractory material (not shown) and a low resistive conductor layer (not shown).

In common with the gate conductors 121 and 124b, it is preferable that the sides of the data conductors 171, 172, 175a, and 175b may be inclined from the insulating substrate 110 at about 30° to 80°.

A passivation layer 180 is formed on the data conductors 171, 172, 175a, and 175b, the exposed semiconductors 154a and 154b, and the gate insulating layer 140.

The passivation layer 180 is made of an inorganic insulating material or an organic insulating material, and the surface of the passivation layer 180 is flat. For example, the inorganic insulating material may be silicon nitride (SiNx) or silicon dioxide (SiO2), and the organic insulating material may be a poly acryl compound.

The passivation layer 180 may have a dual layer structure formed on an inorganic layer and an organic layer.

A plurality of contact holes 182, 185a, and 185b are formed on the passivation layer 180 to expose the ends 179 of the data lines 171 and the first and second output electrodes 175b. Also, a plurality of contact holes 181 and 184 are formed on the passivation layer 180 and the gate insulating layer 140 to expose the ends 129 of the gate lines 121 and the second input electrodes 124b.

A plurality of pixel electrodes 191, a plurality of connecting members 85, and a plurality of contact assistants 81 and 82 are formed on the passivation layer 180, and are made of a transparent conductive material such as ITO (indium tin oxide) and IZO (indium zinc oxide).

Each pixel electrode 191 is physically and electrically connected to a second output electrode 175b through a contact hole 185b.

Each connecting member 85 is connected to a second control electrode 124b and a first output electrode 175a through the contact holes 184 and 185a.

The contact assistants 81 and 82 are connected to the ends 129 of the gate lines 121 and the ends 179 of the data lines 171 through contact holes 181 and 182. The contact assistants 81 and 82 complement the adhesive property between the ends 129 and 179 of the gate lines 121 and the data lines 171 and an external device, and protect them.

A partition 361 is formed on the passivation layer 180.

The partition 361 defines an opening 365 by surrounding the edges of the pixel electrode 191 as a bank. The partition 361 may be made of an organic insulator having a heat-resisting property and a solvent resistance property such as acrylic resin and polyimide resin, or an inorganic insulator such as SiO₂ or TiO₂. Also, the partition 361 may be formed as a plurality of layers. The partition 361 may be made of a photosensitive material having a black pigment. In this case, the partition 361 functions as a light blocking member, and its manufacturing process is simple.

An organic light emitting member 370 is formed on the opening 365 that is formed on the pixel electrode 191, which is defined by the partition 361.

The organic light emitting member 370 includes an emitting layer for emitting light, and an auxiliary layer (not shown) formed on the bottom and/or the top of the emitting layer for improving the light emitting efficiency.

The emitting layer is made of an organic material or a compound of an organic material and an inorganic material, which emit light with one of primary colors, where the organic material and the compound material may include aluminum tris (8-hydroxyquinoline) (Alq3), anthracene, a distryl compound, a polyfluorene derivative, a (poly)paraphenylenevinylene derivative, a polyphenylene derivative, a polyfluorene derivative, polyvinylcarbazole, a polythiophene derivative, and a compound made of a high polymer doped with a perylene pigment, a cumarine pigment, rodermine pigment, rubrene, perylene, 9,10-diphenylanthracene, tetraphenylbutadiene, Nile red, coumarin, or quinacridone. The OLED display displays images by spatially compositing lights with primary colors emitted from the emitting layer.

The auxiliary layer may be an electron transport layer (not shown) and a hole transport layer (not shown) for balancing electrons and holes, and an electron injecting layer (not shown) and a hole injecting layer (not shown) for enhancing the injection of the electrons and holes. The auxiliary layer may include one or two or more layers among them. The hole transport layer and the hole injecting layer are made of a material having a work function intermediate between that of the pixel electrode 191 and the emitting layer. The electron transport layer and the electron injecting layer are made of a material having a work function intermediate between that of the common electrode 270 and the emitting layer. For example, poly-3,4-ethylenedioxythiophene:polystyrenesulfonate (PEDOT:PSS) may be used as the hole transport layer or the hole injecting layer.

A common electrode 270 is formed on the organic light emitting member 370, where the common electrode 270 is made of an opaque metal such as aluminum, an alloy of magnesium and silver, or an alloy of calcium and silver. The common electrode 270 is formed on the entire substrate, and forms a pair with the pixel electrode 191 to flow the current to the organic light emitting member 370.

In such an OLED display, the first control electrode 124a connected to the gate line 121, the first input electrode 173a connected to the data line 171, and the first output electrode 175a form a switching TFT Qs with the first semiconductor 154a. The channel of the switching TFT Qs is formed at the first semiconductor 154a between the first input electrode 173a and the first output electrode 175a. The second control electrode 124b connected to the first output electrode 175a, the second input electrode 173b connected to the driving voltage line 172, and the second output electrode 175b connected to the pixel electrode 191 form a driving TFT Qd with a second semiconductor 154b. The channel of the driving TFT Qd is formed at the second semiconductor 154b between the second input electrode 173b and the second output electrode 175b.

As described above, the OLED display according to the present embodiment has only one switching TFT and one driving TFT. However, the OLED display according to the present invention may further include at least one TFT and a plurality of lines for driving the TFT for in a complementary mode to prevent the organic light emitting diode (LD) and the driving TFT Qd from degrading even when the OLED display is subjected to extended use so as to prevent the lifetime of the OLED display from being shortened.

The pixel electrode 191, the organic light emitting member 370, and the common electrode 270 form an organic light emitting diode LD. The pixel electrode 191 becomes an anode, and the common electrode 270 becomes a cathode. Alternatively, the pixel electrode 191 becomes a cathode and the common electrode 270 becomes an anode. Also, the sustain electrode 127 and the driving voltage line 172, which are overlapped with one another, form a storage capacitor Cst.

Alternatively, when the semiconductors 154a and 154b are polycrystalline silicon, the semiconductors 154a and 154b include an intrinsic region (not shown) facing the control electrodes 124a and 124b and extrinsic regions (not shown) placed at both sides thereof. The extrinsic region is electrically connected to the input electrodes 173a and 173b and the output electrodes 175a and 175b, and the ohmic contacts 163a, 163b, 165a, and 165b may be eliminated.

Also, the control electrodes 124a and 124b may be placed on the semiconductors 154a and 154b. Herein, the gate insulating layer 140 is placed between the semiconductors 154a and 154b and the control electrodes 124a and 124b. Herein, the data conductors 171, 172, 173b and 175b are placed on the gate insulating layer 140 and are electrically connected to the semiconductors 154a and 154b through contact holes formed on the gate insulating layer 140. Alternatively, the data conductors 171, 172, 173b, and 175b may be electrically connected to the semiconductors 154a and 154b by being placed under the semiconductors 154a and 154b.

Specifically, the thin film pattern 115 shown in FIG. 2 and FIG. 3 denotes a switching TFT Qs, a driving TFT Qd, and an organic light emitting diode LD formed on the display region of the insulating substrate 110.

An encapsulation member 400 is formed on the side and the top of a thin film pattern 115 of FIG. 2 and FIG. 3. Specifically, an encapsulation member 400 is formed on the side and the top of a common electrode 270 of FIG. 4 to FIG. 6.

The encapsulation member 400 protects a pixel electrode 191, an organic light emitting member 370, and a common electrode 270 from moisture or air penetrating thereto from the outside.

In the present embodiment, the encapsulation member 400 includes alumina particles 420 that are heat conductive particles, and a sealing resin 411 containing at least one of an ultraviolet hardener (not shown) and a heat hardener (not shown).

The sealing resin 411 is made of at least one of poly-acetylene, poly-imide, and epoxy resin. Although the thickness of the encapsulation member 400 including the sealing resin 411 is not critical, the encapsulation member 400 including the sealing resin 411 may be formed at a thickness of about 5 μm to 100 μm.

The thermal conductivity of the alumina particles 420 is about 10 W/mK to 35 W/mK.

The alumina particles 420 are of a plurality of sizes, more particularly they include the first spherical particles 422 which are the largest particles, the second spherical particles 424 which are the second largest particles, and the third spherical particles 426 which are the smallest particles.

The diameter of the first particles 422 may be from about 5 μm to about 100 μm, the diameter of the second particles 424 may be from about 2 μm to about 20 μm, and the diameter of the third particles 426 may be from about 0.1 μm to about 5 μm.

Spherical particles 422, 424, and 426 are irregularly distributed in the sealing resin 411. It is preferable that the overall volume of the distributed spherical particles 422, 424, and 426 may be about 5% to 75% of the entire volume of the sealing resin 411 in view of thermal conductive efficiency, moisture and air blocking efficiency, as well as achieving suitable sealing characteristic.

Alumina particles 420 may have shapes other than the spherical. The alumina particles 420 may include two types of spherical particles having different diameters or more than four types of spherical particles having different diameters. And alumina particles 420 may be formed as spherical particles with a uniform diameter.

The OLED display according to an embodiment of the present invention may reduce the moisture and air penetrating the pixel electrode 191, the organic light emitting member 370, and the common electrode 270, and the deterioration thereof by rapidly discharging heat generated from the pixel electrode 191, the organic light emitting member 370, and the common electrode 270 to the outside. These advantages of the OLED display according to the present invention will be described with reference to FIG. 5A, FIG. 5B, and FIG. 6.

As shown in FIG. 5A, FIG. 5B, and FIG. 6, the electrodes 191 and 270 and an organic light emitting member 370 may generate heat if the OLED display is self-emissive. The generated heat is discharged to the outside by passing through the common electrode 270 and the encapsulation member 400 due to heat conductivity.

The average heat conductivity of the sealing resin, including auxiliary particles such as a moisture absorbent formed on at least one of poly-acetylene, poly-imide, and epoxy resin, is about 0.3 to 9 W/mK.

If the alumina particles 420 are properly distributed in the sealing resin 411, the heat passing through the common electrode 270 is quickly discharged to the outside by passing through the alumina particles 420 having superior heat conductivity. Therefore, it can prevent the pixel electrode 191, the organic light emitting member 370, and the common electrode 270 from being excessively heated by the heat generated from the self-emitted light.

The distributed alumina particles 420 may be formed as spherical particles with a uniform diameter. However, it is preferable that the alumina particles 420 are formed of circular particles with different diameters.

As shown, if the alumina particles 420 are composed of three types of circular particles 422, 424, and 426, each having different diameters, the spherical particles 424 and 426 having smaller diameters than the spherical particles 422 may be easily disposed between the spherical particles 422 having the largest diameter in the sealing resin 411. Therefore, the heat is more effectively transferred from the common electrode 270 to the outside of the OLED display because the contact surface of the alumina particles 420 is increased.

Meanwhile, the air or moisture from outside of OLED display may penetrate to the pixel electrode 191, the organic light emitting member 370, and the common electrode 270 by passing through the encapsulation member 400. In this case, the alumina particles 420 distributed in the sealing resin 411 block penetration of the air or the moisture and create a barrier in the penetration path. Therefore, air or moisture penetrating to the pixel electrode 191, the organic light emitting member 370, and the common electrode 270 is reduced.

According to the embodiment of the present invention, therefore, the alumina particles 420 distributed in the sealing resin 411 reduce the air or moisture penetrating to the pixel electrode 191, the organic light emitting member 370, and the common electrode 270 from the outside. Additionally, the alumina particles 420 quickly discharge the heat generated from the pixel electrode 191, the organic light emitting member 370, and the common electrode 270 to the outside. Therefore, the performance degradation of the OLED display may be reduced and the lifetime of the OLED display may be extended by minimizing the degradation caused by moisture, air, and heat.

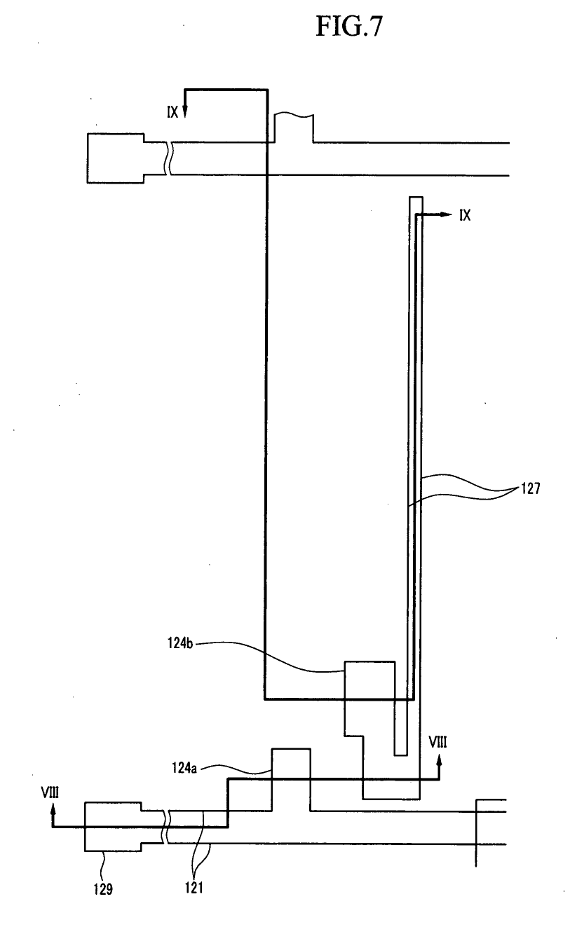

Hereinafter, a method of manufacturing an OLED display according to an embodiment of the present invention will be described with reference to FIG. 7 to FIG. 25.

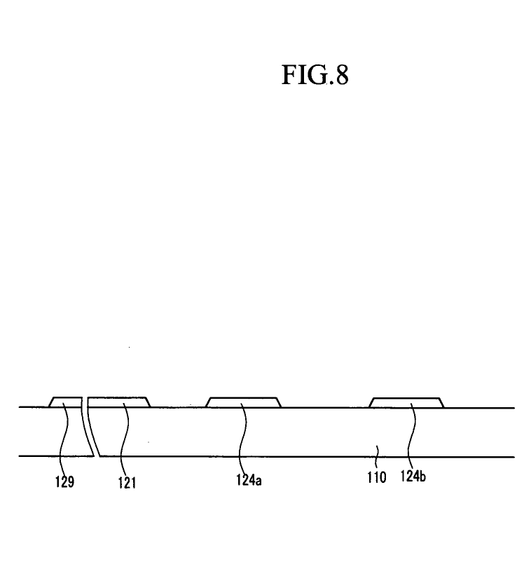

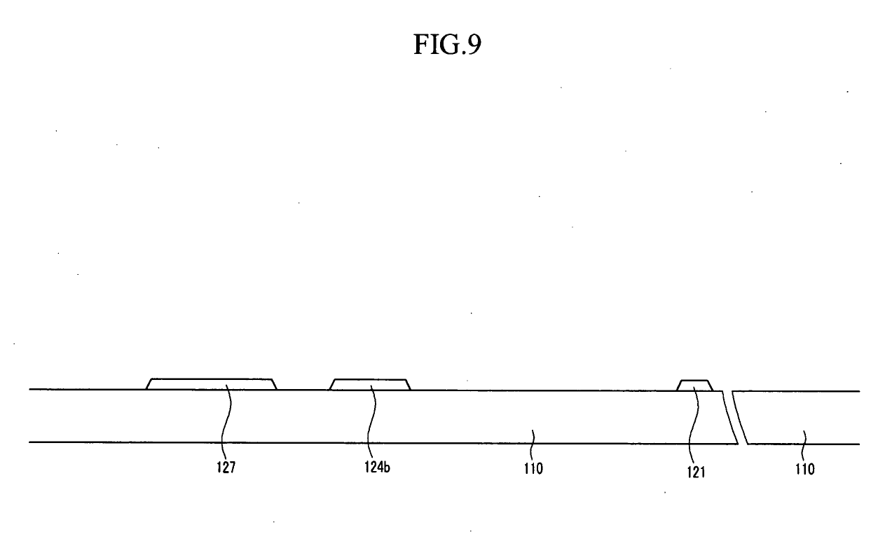

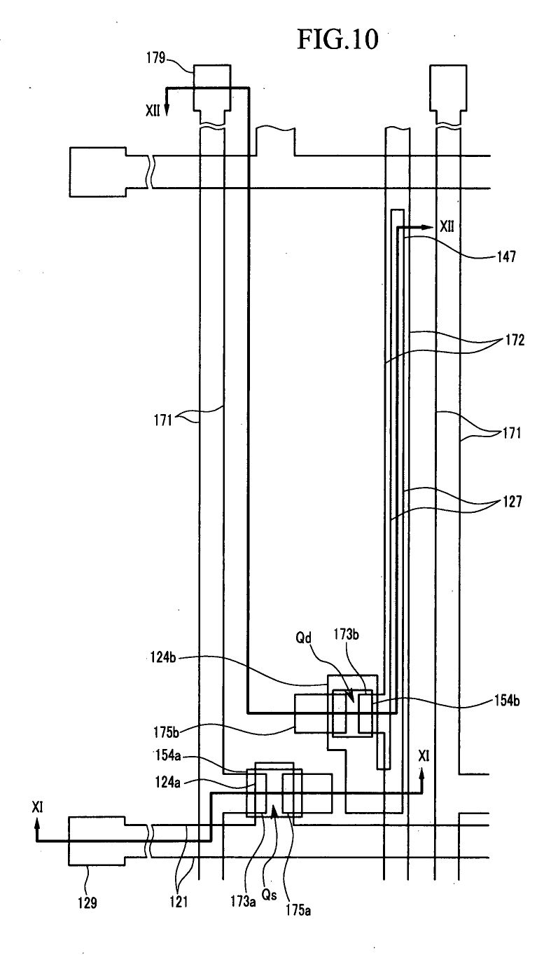

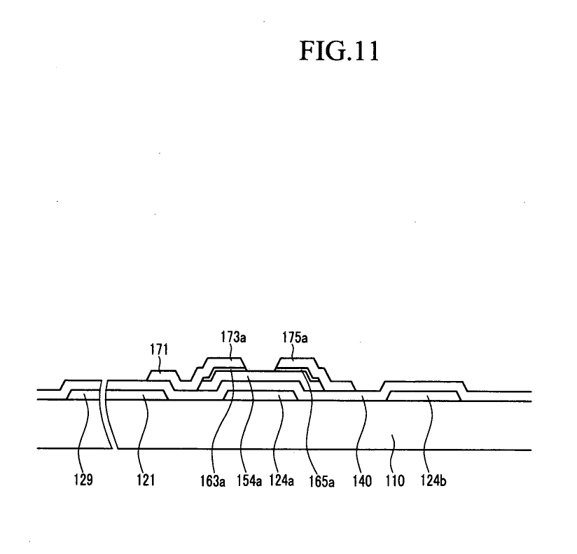

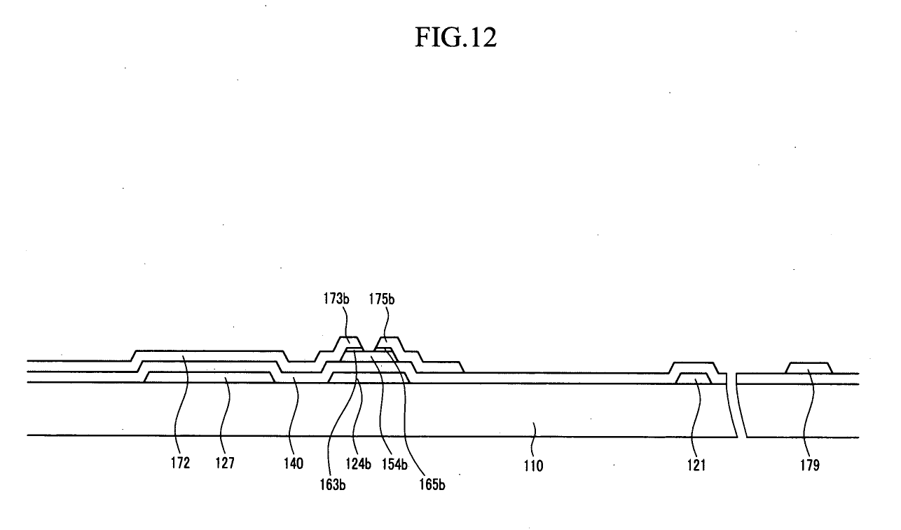

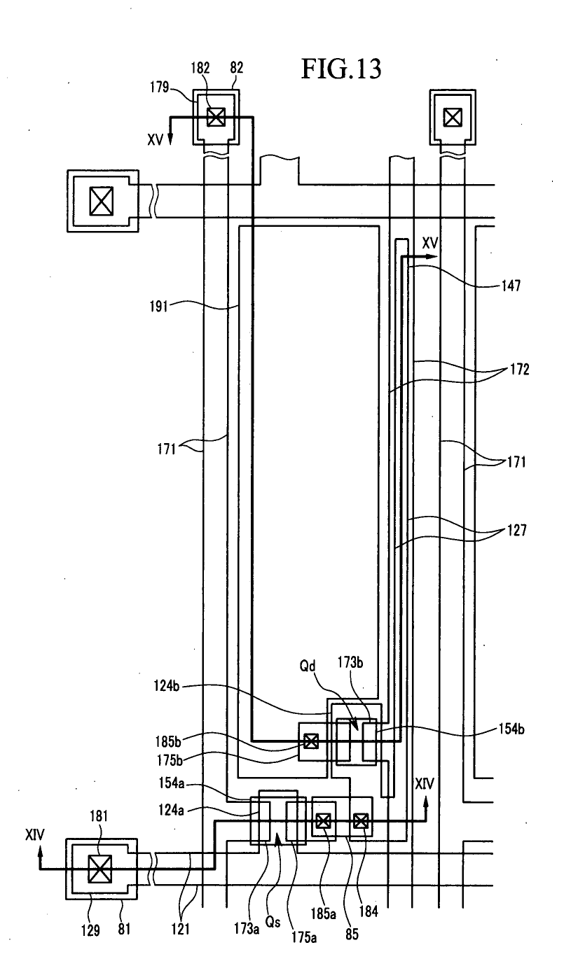

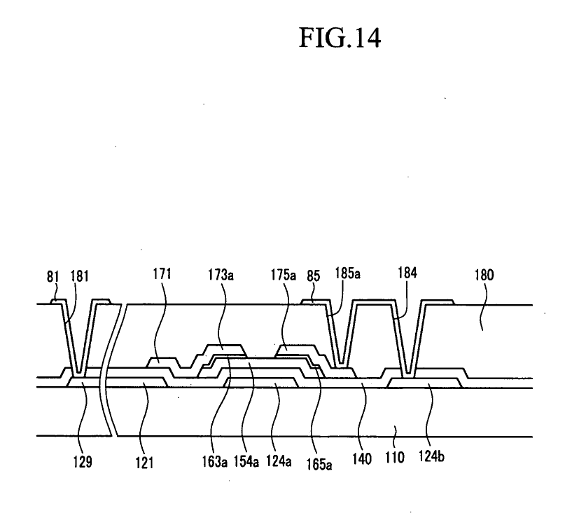

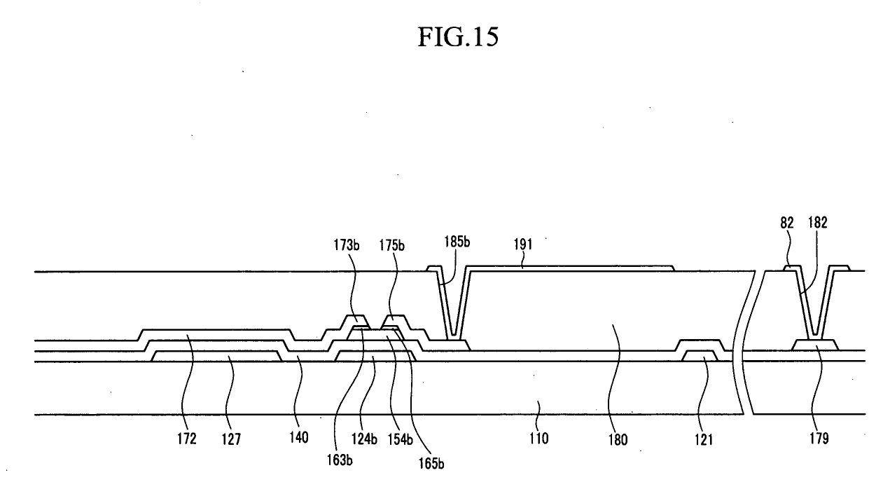

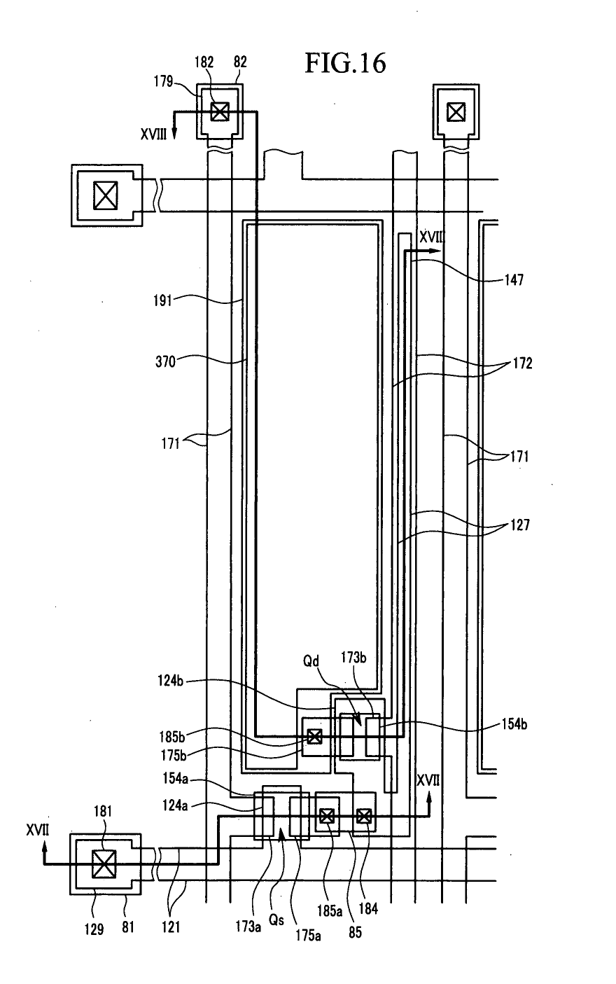

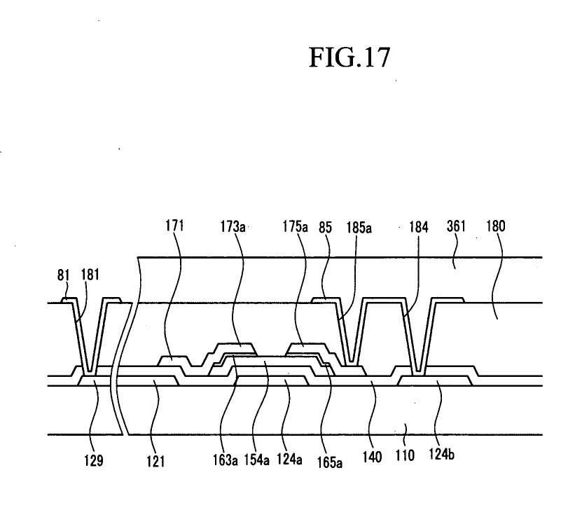

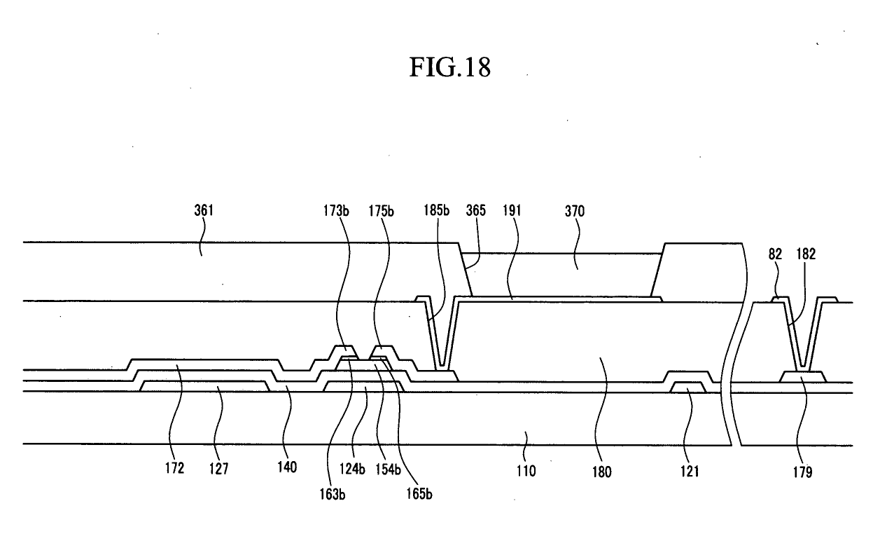

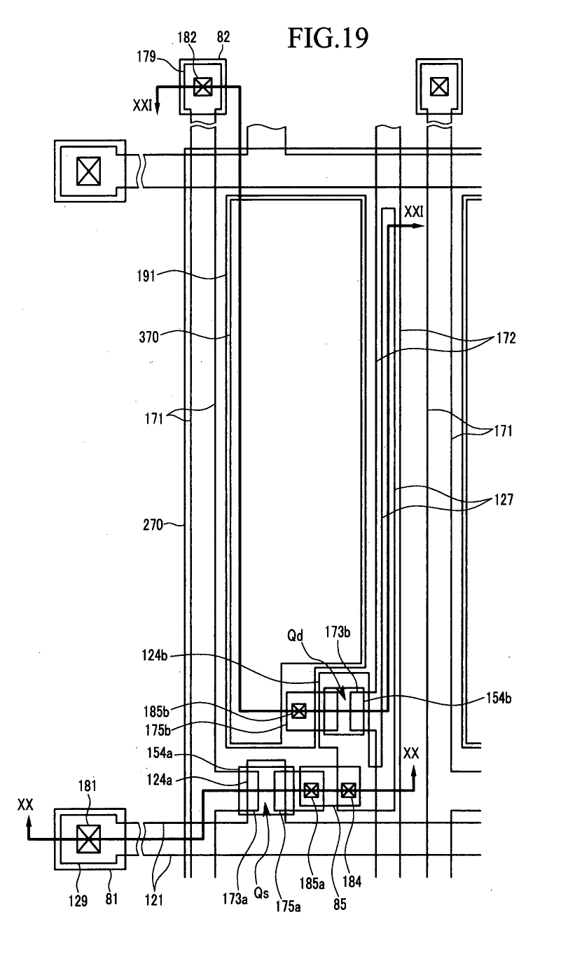

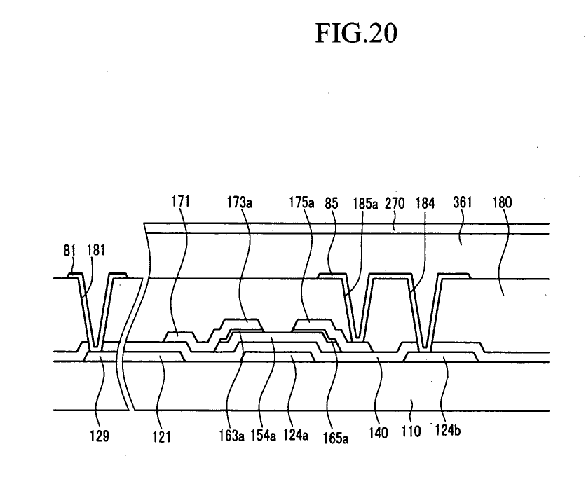

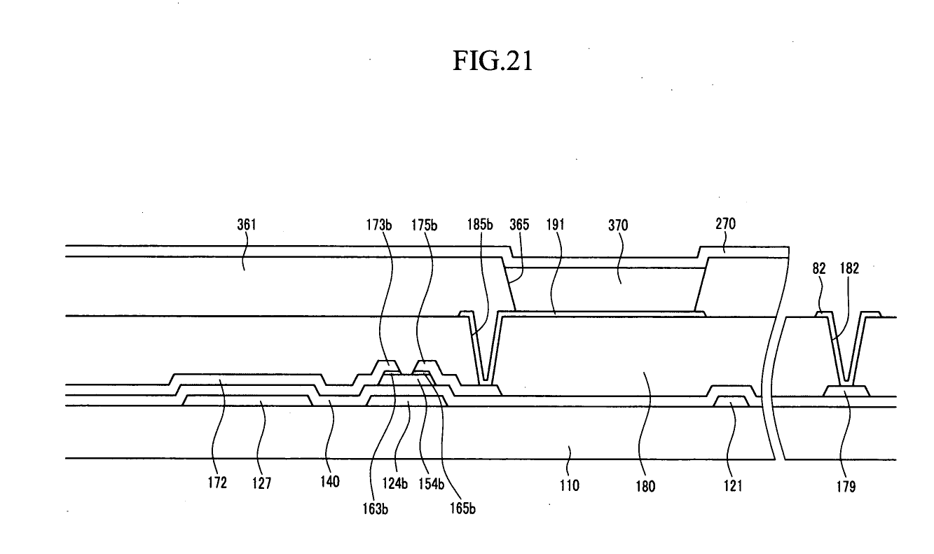

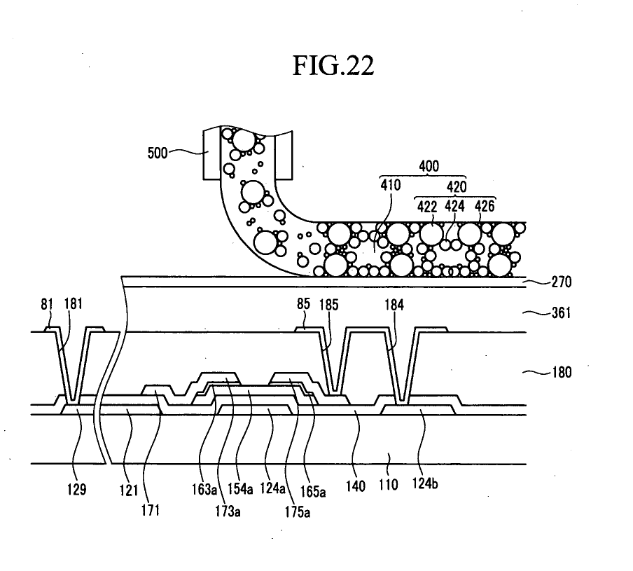

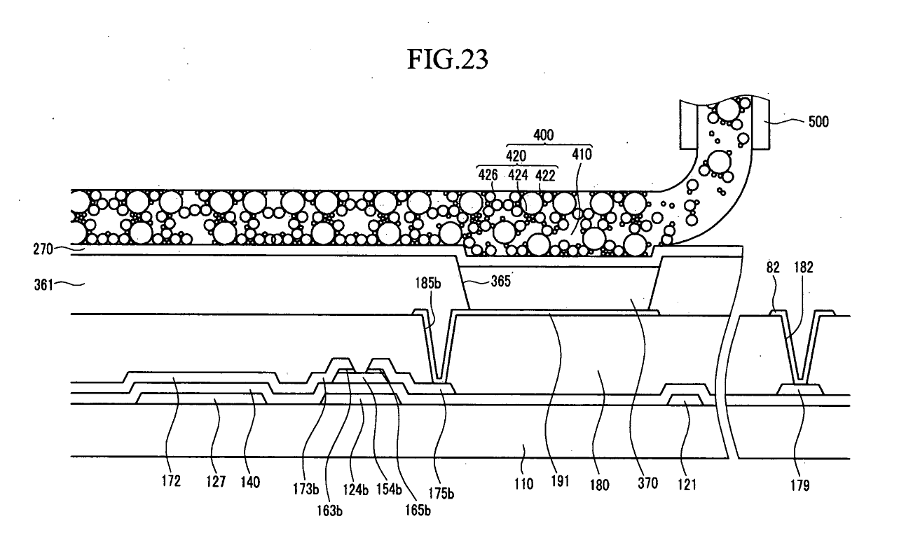

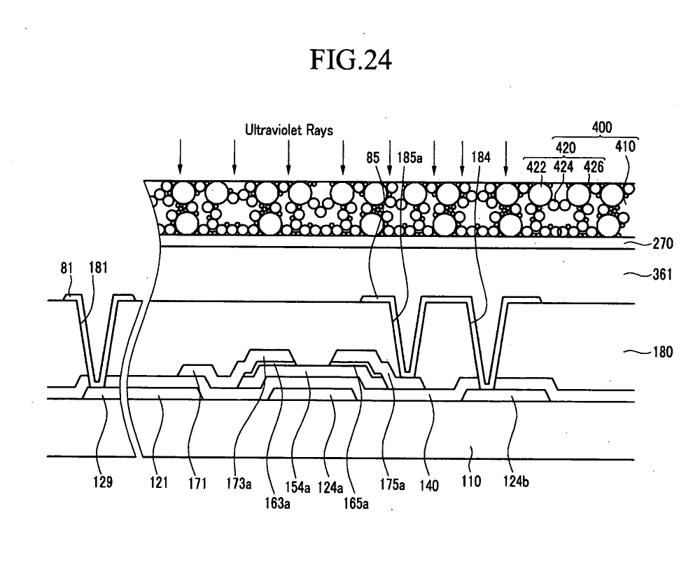

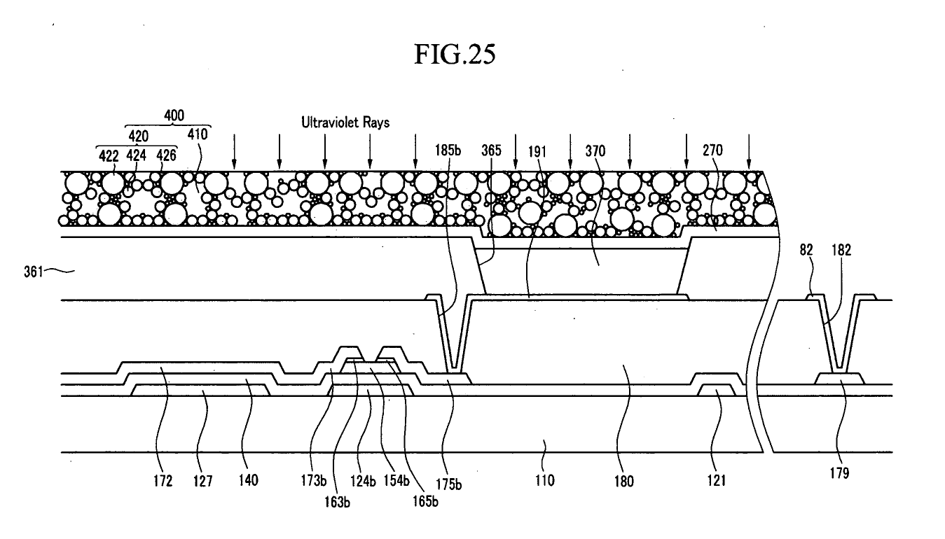

FIG. 7, FIG. 10, FIG. 13, FIG. 16, and FIG. 19 are layout views of the OLED display shown in FIG. 4 to FIG. 6 for describing a method of manufacturing the OLED display according to an embodiment of the present invention, FIG. 8 and FIG. 9 are cross-sectional views of the OLED display shown in FIG. 7 taken along the line VIII-VIII and the line IX-IX, FIG. 11 and FIG. 12 are cross-sectional views of the OLED display shown in FIG. 10 taken along the line XI-XI and the line XII-XII, FIG. 14 and FIG. 15 are cross-sectional views of the OLED display shown in FIG. 13 taken along the line XIV-XIV and the line XV-XV, FIG. 17 and FIG. 18 are cross-sectional views of the OLED display shown in FIG. 16 taken along the line XVII-XVII and the line XVIII-XVIII, FIG. 20 and FIG. 21 are cross-sectional view of the OLED display shown in FIG. 19 taken along the line XX-XX and the line XXI-XXI, FIG. 22 and FIG. 23 are cross-sectional views of FIG. 20 and FIG. 21, and FIG. 24 and FIG. 25 are cross-sectional views of FIG. 22 and FIG. 23.

As shown in FIG. 7 to FIG. 9, gate conductors including a plurality of gate lines 121 having a first control electrode 124a and the end 129 thereof, and a plurality of second control electrodes 124b having a sustain electrode 127 are formed on a transparent insulating substrate 110.

As shown in FIG. 10 to FIG. 12, a plurality of first and second extrinsic semiconductors (not shown) and the first and second semiconductors 154a and 154b are formed by continuously stacking a gate insulating layer 140, an intrinsic amorphous silicon layer, and an extrinsic amorphous silicon layer, and photo-etching the extrinsic amorphous silicon layer and the intrinsic amorphous silicon layer.

Then, data conductors including a plurality of data lines 171 having the first input electrode 173a and the end 179 thereof, a driving voltage line 172 having the second input electrode 173b, and a plurality of the first and second output electrodes 175a and 175b, made of an aluminum or other highly conductive alloy, are formed.

Continuously, ohmic contacts 163a, 165a, 163b, and 165b are formed by removing the exposed portions of the extrinsic semiconductor that are not covered by data conductors 171, 172, 175a, and 175b. Then, the predetermined portions of the first and second semiconductors 154a and 154b under the ohmic contacts are exposed.

Then, a passivation layer 180 is stacked through chemical vapor deposition or a printing method, and a plurality of contact holes 181, 182, 184, 185a, and 185b are formed by photo-etching the passivation layer 180. The contact holes 181, 182, 184, 185a, and 185b expose the ends 129 of gate lines 121, the ends 179 of data lines 171, the second control electrodes 124b, the first output electrodes 175a, and the second output electrodes 175b.

As shown in FIG. 13 to FIG. 15, a transparent conductor made of ITO (indium tin oxide) or IZO (indium zinc oxide) is formed on the passivation layer 180 through sputtering, and a plurality of pixel electrodes 191, a plurality of connecting members 85, and a plurality of contact vias 81 and 82 are formed by photo-etching the transparent conductor.

As shown in FIG. 16 to FIG. 18, a partition 361 having an opening 365 is formed on the pixel electrode 191 by coating a photosensitive organic insulating layer through spin coating, and exposing and developing the photosensitive organic insulating layer.

Then, a light emitting member 370 having a hole transport layer (not shown) and an emitting layer (not shown) is formed on the opening 365 on the pixel electrode 191. The light emitting member 370 may be formed through a solution process such as an inkjet printing or evaporation. Among them, the inkjet method that moves the inkjet head and deposits the solution to the opening 365 is preferable. In this case, a drying operation is performed after forming each layer.

As shown in FIG. 19 to FIG. 21, a common electrode 270 is formed on the partition 361 and the light emitting member 370 by depositing aluminum thereon through sputtering.

As shown in FIG. 22 and FIG. 23, a sealing resin material 410 with alumina particles 420 distributed therein is formed on the common electrode 270 using a nozzle coater 500. Herein, the sealing resin material 410 is in a gel state and the alumina particles 420 are heat conductive particles. The sealing resin material 410 may be formed using a screen printing method.

As shown in FIG. 24 and FIG. 25, the sealing resin material 410 formed on the common electrode 270 is hardened using ultraviolet rays so as to form the encapsulation member 400 having a sealing resin 411.

The manufacturing method of the present embodiment can manufacture an OLED display that can reduce air and moisture penetration into the pixel electrode 191, the organic light emitting member 370, and the common electrode 270 using the alumina particles 420 distributed in the sealing resin 411, and can quickly discharge the heat generated from the pixel electrode 191, the organic light emitting member 370, and the common electrode 270 to the outside.

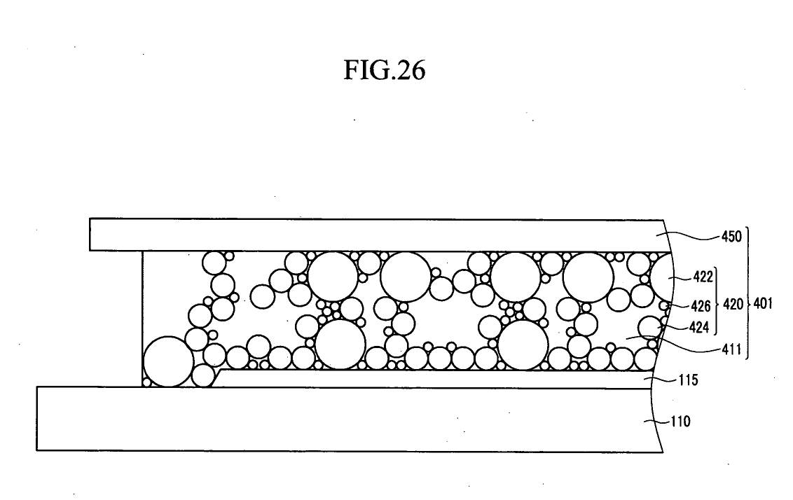

Hereinafter, an OLED display according to another embodiment of the present invention will be described based on differences from the OLED display shown in FIG. 3, with reference to FIG. 26.

FIG. 26 is a cross-sectional view of an OLED display according to another embodiment of the present invention.

The OLED shown in FIG. 26 is identical to the OLED display shown in FIG. 3 except that an encapsulation member 401 further includes a protection substrate 450 formed on a sealing resin 411.

The insulating protection substrate 450 adhered on the sealing resin 411 protects the sealing resin 411 and further reduces moisture and air penetration into the organic light emitting member 370 by blocking the moisture and the air.

A method of manufacturing the OLED display according to another embodiment is also identical to the method of manufacturing the OLED display shown in FIG. 3 through the forming of the gel type sealing resin material 410 having the alumina particles 420 on the common electrode 270. However, they are different in view of forming an encapsulation member 401 by closely adhering the protection substrate 450 on the sealing resin material 410 and hardening the sealing resin material 410 using ultraviolet rays. Protective substrate 450 may be of transparent glass or plastic.

Alternatively, the encapsulation member 401 of the OLED display may be formed using other manufacturing methods different from the method for manufacturing an OLED display according to the above embodiment of the present invention.

For example, the encapsulation member 401 is formed by coating a sealing resin material 410 including alumina particles 420 on the entire surface of the protection substrate 450, and closely adhering the protection substrate 450 with the sealing resin material 410 coated to the common electrode 270, and hardening the resultant thereof.

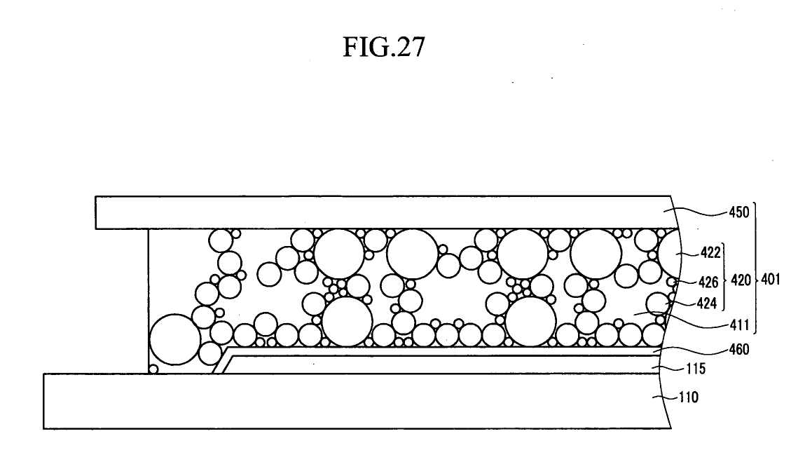

Hereinafter, an OLED display according to another embodiment of the present invention will be described based on the differences from the OLED display shown in FIG. 26, with reference to FIG. 27.

FIG. 27 is a cross-sectional view of an OLED display according to another embodiment of the present invention.

The OLED display shown in FIG. 27 is identical to the OLED display shown in FIG. 26 except for the inclusion of a buffer layer 460 which is interposed between a common electrode 270 and a sealing resin 411 including alumina particles 420.

The buffer layer 460 may be an organic layer formed on the common electrode 270 of a thin film pattern 115 through spin-coating or slit coating, and an inorganic layer formed through depositing.

When the OLED display shown in FIG. 27 is manufactured, some of the alumina particles 420 of the sealing resin material 410 are projected toward to the common electrode by the weight of the protection substrate 450 or the pressure applied to the protection substrate 450 while the protection substrate 450 is closely adhered on the sealing resin material 410. The buffer layer 460 prevents the projected alumina particles 420 from touching the common electrode 270 so as to prevent the weak common electrode 270 from being damaged by the alumina particles 420.

Hereinafter, an OLED display according to another embodiment of the present invention will be described based on the differences from the OLED display shown in FIG. 3.

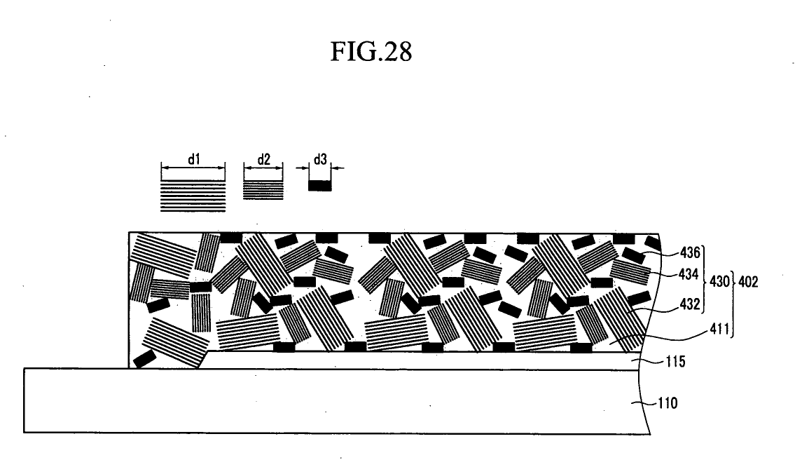

FIG. 28 is a cross-sectional view of an OLED display according to another embodiment of the present invention.

As shown in FIG. 28, the OLED display according to another embodiment is identical to the OLED display shown in FIG. 3, except that the sealing resin 411 of encapsulation member 402 includes graphite particles 430 as the heat conductive particles instead of the alumina particles 420.

The graphite particles 430 have the same function as the alumina particles 420, and the heat conductivity of the graphite particles 430 is about 100 to 200 W/mK.

The graphite particles 430 are plate-shaped, and the graphite particles 430 include first plate-shaped particles 432, second plate-shaped particles 434, and third plate-shaped particles 436. The first plate-shaped particles 432 are the largest among them, the second plate-shaped particles 434 are the second largest, and the third plate-shaped particles 436 are the smallest.

Herein, the first plate-shaped particle 432 may have a length of a long side of about 5 μm to 100 μm of, the second plate-shaped particle 434 may have a length of a long side of about 2 μm to 20 μm, and the third plate-shaped particle 436 may have a length of a long side of about 0.1 μm to 5 μm.

Graphite particles suitable for use in practicing the present invention can be obtained from Sigma-Aldrich (3050 Spruce St St. Louis. MO. USA, catalog No: 496588, 496596, 282863)

The plate particles 432, 434, and 436 are distributed in the sealing resin 411 irregularly. The volume of the distributed plate particles 432, 434, and 436 may be selected to be about 5% to 75% of the entire sealing resin 411 in view of heat conductivity, moisture and air blocking efficiency, as well as providing a good seal as in the aforementioned embodiment.

The graphite particles 430 may have shapes other than the plate shape. Also, the graphite particle 430 may include two types of plate particles each having different length of the long sides, or more than four types of plate particles each having a different length of the long sides. The graphite particle 430 may be formed as plate-shaped particles with a uniform length of long sides.

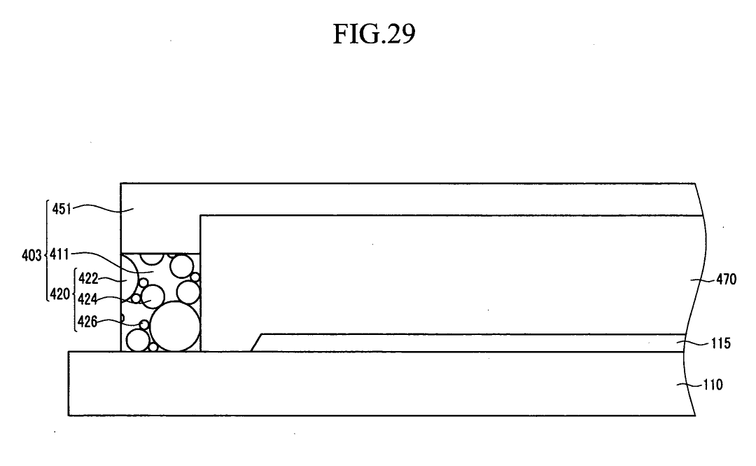

Hereinafter, an OLED display according to another embodiment will be described based on the differences from the OLED display shown in FIG. 26, with reference to FIG. 29.

FIG. 29 is a cross-sectional view of an OLED display according to another embodiment of the present invention.

The OLED display shown in FIG. 29 is identical to the OLED display shown in FIG. 26, except that a sealing resin 411 of an encapsulation member 403 is formed along a non-display region of an insulating substrate 110 instead of closely adhering to the common electrode 270 of thin film pattern 115, and with the further exception that the sealing resin 411 is adhered only at the edges of the protection substrate 451.

Accordingly, a space 470 is formed between the common electrode 270 and the encapsulation member 403, and the space 470 is filled with an inert gas or nitrogen for preventing air or moisture from penetrating from the outside.

According to the OLED display according to another embodiment shown in FIG. 2, the heat output from the common electrode 270 is circulated through convection in the space 470 filed with the nitrogen or the inert gas. The circulated heat is quickly discharged to the outside through the sealing resin 411 having the alumina particles 420 having superior heat conductivity. Also, the alumina particles 420 may reduce air or moisture penetration through the sealing resin 411.

The OLED displays according to the embodiments shown in FIG. 26 to FIG. 29 and the manufacturing methods thereof may provide the same results as the OLED display shown in FIG. 3 and the manufacturing method thereof.

As described above, the OLED display according to the present invention reduces air and moisture penetration of the organic light emitting member or the electrode from the outside using heat conductive particles distributed in the sealing resin, and quickly discharges the heat generated from the organic light emitting member or the electrode to the outside. Therefore, the display performance of the OLED display may be substantially prevented from degrading by reducing the deterioration caused by moisture, air, and heat. Also, the lifetime thereof can be extended.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display comprising:
an insulating substrate having a display region and a non-display region formed outside of the display region;
a plurality of thin film transistors formed on the display region of the insulating substrate;
a plurality of pixel electrodes connected to associated ones of the thin film transistors;
a plurality of organic light emitting members formed on associated ones of the plurality of pixel electrodes;
a common electrode formed on the organic light emitting members; and
an encapsulation member formed on the common electrode, the encapsulation member comprising a sealing resin including heat conductive particles distributed therein, where the heat conductive particles have a heat conductivity of about 10 W/mK or greater.

2. The OLED display of claim 1, wherein the heat conductive particles have at least two different sizes.

3. The OLED display of claim 1, wherein the heat conductive particles include at least one of alumina particles and graphite particles.

4. The OLED display of claim 3, wherein the heat conductivity of the alumina particles is from about 10 W/mK to 35 W/mK.

5. The OLED display of claim 3, wherein the heat conductivity of the graphite particles is about 100 W/mK to 200 W/mK.

6. The OLED display of claim 3, wherein:
the heat conductive particles include alumina particles; and
the alumina particles are spherical and are of at least two different sizes.

7. The OLED display of claim 3, wherein:
the heat conductive particles include graphite particles; and
the graphite particles are of at least two different sizes of plate-shaped particles.

8. The OLED display of claim 1, wherein the volume of the heat conductive particles is about 5% to 75% of the volume of the sealing resin.

9. The OLED display of claim 1, wherein a thickness of the encapsulation member is from about 5 μm to 100 μm.

10. The OLED display of claim 1, wherein:
the heat conductive particles are spherical alumina particles of first, second and third groups of particles having different diameters;
wherein the diameter of the first group of particles is from about 5 μm to 75 μm,
the diameter of the second group of particles is from about 2 μm to 20 μm, and
the diameter of the third group of particles is from about 0.1 μm to 5 μm.

11. The OLED display of claim 1, wherein:
the heat conductive particles are graphite particles, and include first, second and third groups of plate-shaped particles,
wherein, a length of a long side of the first plate-shaped particles is about from 5 μm to 50 μm,
a length of a long side of the second plate-shaped particles is about 2 μm to 20 μm, and
a length of a long side of the third plate-shaped particles is about 0.1 μm to 5 μm.

12. The OLED display of claim 1, wherein the sealing resin is formed on at least a portion of the common electrode.

13. The OLED display of claim 1, wherein the encapsulation member further includes a protective substrate adhered on the sealing resin on a side opposite the common electrode.

14. The OLED display of claim 13, further comprising a buffer layer formed between the common electrode and the encapsulation member.

15. The OLED display of claim 14, wherein the buffer layer is at least one of an organic layer and an inorganic layer.

16. The OLED display of claim 1, wherein the encapsulation member further includes a protective substrate adhered on the sealing resin to cover the common electrode, and
further wherein the sealing resin includes a portion positioned in the non-display region of the insulating substrate.

17. A method of manufacturing an organic light emitting diode (OLED) display, the method comprising:
forming a plurality of thin film transistors on a display region of an insulating substrate having the display region and a non-display region;
forming a plurality of pixel electrodes connected to associated ones of the thin film transistors;
forming a plurality of organic light emitting members, one for each of the pixel electrodes;
forming a common electrode on the organic light emitting members; and
forming an encapsulation member comprising a sealing resin including heat conductive particles distributed therein, where the heat conductive particles have heat conductivity of about 10 W/mK or greater.

18. The method of claim 17, wherein the forming of the encapsulation member comprises:
forming the encapsulation member along at least a portion of the non-display region; and
hardening the encapsulation member using at least one of heat and ultraviolet light.

19. The method of claim 17, further comprising, between forming the common electrode and the forming of the encapsulation member, forming a buffer layer on the common electrode.

20. The method of claim 17, wherein, forming the encapsulation member, comprises including in the sealing resin heat conductive particles of a plurality of sizes.

21. The method of claim 17, wherein, in the forming of the encapsulation member, the heat conductive particles distributed in the sealing resin include at least one of alumina particles and graphite particles.
